(19) United States
(12) Patent Application Publication
(10) Pub. No.: US 2008/0078324 A1
(43) Pub. Date: Apr. 3, 2008

(54) Fluidized bed CVD arrangement

(76) Inventors: Jeffrey A. Halfinger, Lynchburg, VA (US); Scott G. Nagley, Forest, VA (US); William C. Richardson, Forest, VA (US); Bruce L. Tomlin, Lynchburg, VA (US); Joseph T. Keeley, Lynchburg, VA (US)

Correspondence Address: BWX TECHNOLOGIES, INC.;LAW DEPARTMENT - INTELLECTUAL PROPERTY, 91 STIRLING AVENUE, (MAIL STATION BWO11E), BARBERTON, OH, 44203-0271, US

(21) Appl. No.: 11/528,930

(22) Filed: Sep. 28, 2006

(51) Int. Cl. C23C 16/00

(52) U.S. Cl. 118/715

(57) ABSTRACT

A means of scaling up fluidized bed chemical vapor deposition (FBCVD) production by using two or more small reactors instead of one large reactor. Each reactor has its own process gas delivery and exhaust lines. The furnace heating is designed such that each reactor has its own heater or there may be one large heater designed to keep the group of reactors at a constant temperature. This allows the shut down of a failed reactor without affecting production from other reactors.

This invention was made, in part, with government support under Contract No. DE-AC07-05ID14517 awarded by the Department of Energy. The United States government has certain rights in this invention.

### FIELD AND BACKGROUND OF INVENTION

The invention is generally related to chemical vapor deposition to manufacture coated material and more particularly to scaling up the process to manufacture large quantities of coated material.

In current practice, a fluidized bed chemical vapor deposition (FBCVD) system consists of a liquid-cooled furnace and covers, a fluidized bed reactor configured to produce coated material, a process gas preparation and delivery system, a heating element, a power supply, and an effluent scrubbing system. In a FBCVD process, the uncoated substrates (e.g., spheres or kernels) are suspended (fluidized) in an inert gas stream within the reactor. When the reactor is heated to the coating temperature by the furnace, gaseous reactants are flowed into the reactor through the injector. The reactants form a coating on the suspended substrates. For example, methyltrichlorosilane and hydrogen react to form silicon carbide.

Typically, processes are developed in a small reactor to determine the feasibility of the process and, when proven, the process is scaled to a larger furnace/reactor. The hydrodynamics, heat transfer, reaction chemistry, and particle wall interactions of FBCVD processes is very complex and the scaling factors (for gas flow and substrate load) are usually not linear with furnace size. Thus, there is a risk when scaling up a FBCVD process that the coated product will not meet required specifications (e.g. sphericity, density, coating thickness, and phase/chemical composition).

Current practice in scaling a FBCVD process to manufacture large quantities of material is to first develop the process in a research system that uses a small fluidized bed reactor. Next, the process is scaled up to manufacturing by using a large reactor. Sometimes an intermediate size reactor is used. Generally, a FBCVD process does not scale linearly with the size of the reactor (e.g. doubling the reactor volume is not compensated in scaling by doubling the flow of reactant gases). This means that scaling up the process can be expensive and risky.

### SUMMARY OF INVENTION

The present invention addresses the deficiencies in the known scaling processes. The invention provides a means of scaling up FBCVD production by using two or more small reactors instead of one large reactor. Thus, a FBCVD process developed in a sub-scale reactor can be used in a production reactor with minimal risk. Each reactor has its own process gas delivery and exhaust lines. The furnace heating is designed such that each reactor has its own heater or there may be one large heater designed to keep the group of reactors at a constant temperature. This allows the shut down of a failed reactor without affecting production from other reactors.

The various features of novelty which characterize the invention are pointed out with particularity in the claims annexed to and forming part of this disclosure. For a better understanding of the present invention, and the operating advantages attained by its use, reference is made to the accompanying drawings and descriptive matter, forming a part of this disclosure, in which a preferred embodiment of the invention is illustrated.

### BRIEF DESCRIPTION OF THE DRAWINGS

In the accompanying drawings forming a part of this specification and in which reference numerals shown in the drawings designate like or corresponding parts throughout the same:

FIG. 1 is a top view of the invention.

FIG. 2 is a view taken along lines 2-2 in FIG. 1.

FIG. 3 illustrates an alternate embodiment of the invention.

FIG. 4 is a view taken along lines 4-4 in FIG. 3.

### DESCRIPTION OF THE PREFERRED EMBODIMENTS

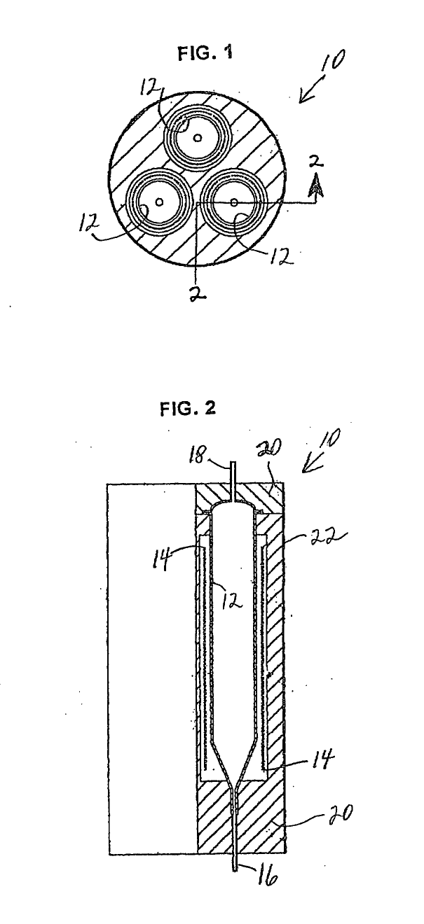

The invention is generally indicated by numeral 10 in FIGS. 1 and 2. The invention is generally comprised of multiple small reactors 12 placed in one large furnace.

Each reactor 12 is provided with its own heating element 14. Each reactor 12 has its own intake line 16 for delivery of the process gas into the reactor and its own exhaust line 18 for exhausting the process gas. The exhaust lines 18 for the reactors 12 lead to a common effluent scrubber not shown. Insulation 20 is held in place around the reactors 12 and heating elements 14 by a furnace jacket 22.

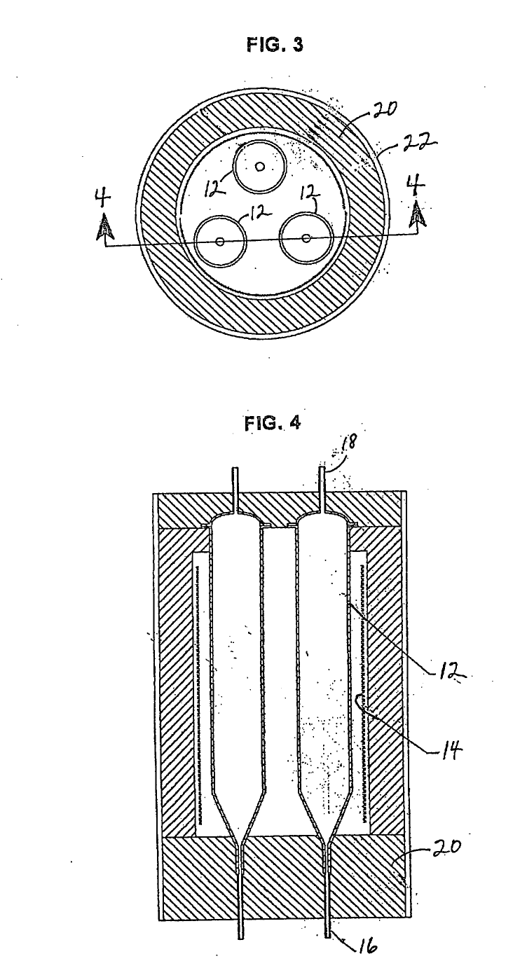

FIGS. 3 and 4 illustrate an alternate embodiment wherein one heating element 14 is used for all of the reactors 12.

In operation, the process of coating substrates is carried out in essentially the same manner as when using a single large reactor. The difference is the use of multiple smaller reactors that eliminate the risk and difficulty normally associated with scaling up a newly developed FBCVD process.

The invention has two primary advantages over scaling a process for use in a larger reactor. One is that development costs are not required if multiple small or intermediate reactors (the same size used to develop the FBCVD process) are used in a large furnace. A second advantage is that the use of multiple reactors allows stopping the coating process in one reactor without losing the entire batch of substrates. The coating in one reactor can be stopped while the others continue without losing the entire furnace run. When only a single large reactor is used, as in the current known art, the entire furnace run is lost if a problem causes the process to be stopped. If the substrates are valuable (e.g., nuclear fuel kernels), significant money can be saved with the ability to continue the process in the remaining reactors according to the inventive concept.

The invention is applicable to any FBCVD process. It is not limited to the number of reactors contained within a furnace. While the description illustrates an example using three reactors, it should be understood that two, three, or more reactors may be used. The invention is not limited by the materials of which the furnace system is constructed or the type of furnace control equipment. Further, the invention is not limited to the design of the furnace or reactor since this would be specific to a process. For example, a particular process may require a thermal gradient in the furnace which would be controlled by the type and amount of insulation and the design of the heating element(s).

While specific embodiments and/or details of the invention have been shown and described above to illustrate the application of the principles of the invention, it is understood that this invention may be embodied as more fully described in the claims, or as otherwise known by those skilled in the art (including any and all equivalents), without departing from such principles.

I/We claim:

1. A fluidized bed chemical vapor deposition arrangement, comprising:
a. a furnace jacket;
b. at least two reactors positioned inside said furnace jacket, with each reactor having intake and exhaust lines; and
c. insulation placed in said furnace jacket around said reactors.

2. The fluidized bed chemical vapor deposition arrangement of claim 1, further comprising a heating element positioned around each reactor.

3. The fluidized bed chemical vapor deposition arrangement of claim 1, further comprising a single heating element positioned around all of the reactors.

4. A means for scaling up a fluidized bed chemical vapor deposition process, comprising:
a. providing at least two reactors, with each reactor having separate process gas intake and exhaust lines; and
b. providing insulation around said reactors.

5. The means of claim 4, further comprising providing a separate heating element around each reactor.

6. The means of claim 4, further comprising providing a heating element around the reactors.
